(19) United States
(12) Patent Application Publication
(10) Pub. No.: US 2016/0374210 A1
(43) Pub. Date: Dec. 22, 2016

(54) MICROELECTRONIC BUILD-UP LAYERS AND METHODS OF FORMING THE SAME

(71) Applicant: Intel Corporation, Santa Clara, CA (US)

(72) Inventors: Brandon C. MARIN, San Diego, CA (US); Trina GHOSH DASTIDAR, Chandler, AZ (US); Yonggang Yong LI, Chandler, AZ (US); Dilan SENEVIRATNE, Phoenix, AZ (US)

(73) Assignee: INTEL CORPORATION, Santa Clara, CA (US)

(21) Appl. No.: 14/905,022

(22) PCT Filed: Feb. 16, 2015
(86) PCT No.: PCT/US2015/016072

§ 371 Date: Jan. 14, 2016

(51) Int. Cl. H05K 3/18; H01L 21/288; H05K 1/03; H01L 23/528; H01L 23/532; H05K 1/09; H01L 21/768; H05K 3/00

(52) U.S. Cl. CPC H05K 3/187; H01L 21/76874; H01L 21/76802; H01L 21/76829; H01L 21/76877; H01L 21/288; H05K 3/0032; H01L 23/528; H01L 23/5329; H01L 23/53228; H05K 1/09; H05K 1/036

(57) ABSTRACT

A build-up layer may be fabricated by forming a microelectronic dielectric layer comprising a dielectric material with a metallization catalyst dispersed therein, forming a primer layer on the microelectronic dielectric layer, and forming a recess through the primer layer and into the dielectric material layer. An activation layer may be formed in or on the exposed microelectronic dielectric layer within the recess, wherein the primer layer acts as a mask. A metal layer may be formed on the activation layer, such as with an electroless process. Thus, the resolution of the metal layer deposition may be precisely controlled by the process used to form the recess.

### TECHNICAL FIELD

Embodiments of the present description generally relate to the field of microelectronic device fabrication, and, more particularly, to metallization structures for build-layers and methods of fabricating the same.

### BACKGROUND

Microelectronic devices are generally fabricated from various components, including, but not limited to, at last one microelectronic die (such as a microprocessor, a chipset, a graphics device, a wireless device, a memory device, an application specific integrated circuit, or the like), at least one passive component (such as resistors, capacitors, inductors and the like), and at least one microelectronic substrate (such as interposers, motherboards, and the like) for mounting the components. The various components may be interconnected to one another through build-up layers comprising a plurality of dielectric layers with a plurality of metallization structures, such as conductive traces and conductive vias formed on and/or through the dielectric layers. These build-up layers may be formed on any of the components within the microelectronic device.

The microelectronic industry is continually striving to produce ever faster and smaller microelectronic devices for use in various electronic products, including, but not limited to portable products, such as portable computers, digital cameras, electronic tablets, cellular phones, and the like. As the size of components, such as microelectronic dice and microelectronic substrates, are reduced, the size of the metallization must also be reduced. Therefore, there is a need to develop metallization structures and methods of fabrication thereof to reduce the size of the metallization structures.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The present disclosure will be described with additional specificity and detail through use of the accompanying drawings, such that the advantages of the present disclosure can be more readily ascertained, in which:

FIG. 1 is a side cross sectional view of a microelectronic dielectric layer comprising a dielectric material having a metallization catalyst dispersed therein, according to an embodiment of the present description.

FIG. 2 is a side cross sectional view of a primer layer formed on the microelectronic dielectric layer, according to an embodiment of the present description.

FIG. 3 is a side cross sectional view of a recess formed through the primer layer and into the dielectric material layer, according to an embodiment of the present description.

FIG. 4 is a side cross sectional view of an activated layer formed within the dielectric material layer in the recess when laser ablation is used to form the recess, according to one embodiment of the present description.

FIG. 5 is a side cross sectional view of an activated layer formed within the dielectric material layer in the recess by immersion in an activation solution, according to another embodiment of the present description.

FIGS. 6 and 7 are side cross sectional views of a metal layer formed on the activated layer by immersion in a deposition solution, according to an embodiment of the present description.

FIG. 8 illustrates a computing device in accordance with one implementation of the present description.

### DESCRIPTION OF EMBODIMENTS

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

Currently, the formation of build-up layers is achieved by forming a dielectric material layer, wherein a surface of this dielectric material layer is roughened, by any appropriate technique, and exposed to a metallization catalyst in an ionic or colloidal solution. Molecules of the metallization catalyst complex with the dielectric material layer and an activation process, such as by reducing chemistry (for example, dimethylamineborane) is used to bring the metallization catalyst to a correct oxidation state to enhance catalyst activity, as will be understood to those skilled in the art. The activated dielectric material layer is then exposed to a solution of a desired metal, such as copper, and a reducing agent, which results in the deposition of a metal layer in areas with the metallization catalyst complexed to dielectric material layer (i.e. the metallization catalyst is required to initiate the metal layer deposition). This process is known in the industry as electroless deposition. However, such methods lack spatial specificity and rely on deposition of the metal layer over relatively large areas through total immersion in catalyst solution.

Embodiments of the present description include methods of fabricating a build-up layer having a high degree of control over the metal layer deposition or “patterning” and include the build-up layers formed with these methods. In one embodiment, a microelectronic dielectric layer may be formed to include a dielectric material with a metallization catalyst dispersed therein. A primer layer may be formed on the microelectronic dielectric layer and a recess may then be formed through the primer layer and into the dielectric material layer with an ablating laser. An activation layer may be formed in or on the exposed microelectronic dielectric layer within the recess, wherein the primer layer acts as a mask. A metal layer may be formed on the activation layer, such as with an electroless process. Thus, the resolution of the metal layer deposition may be precisely controlled by the process used to form the recess, such as the high precision of the ablating laser.

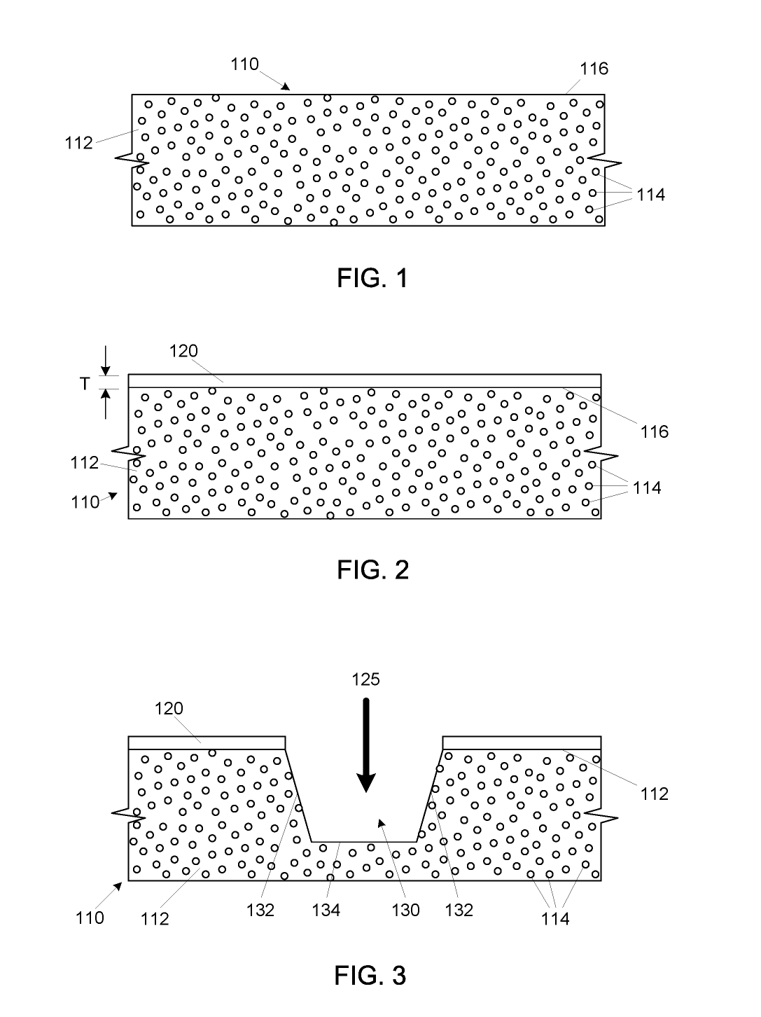

As shown in FIG. 1, a microelectronic dielectric layer 110 may be formed, wherein the microelectronic dielectric layer 110 may comprise a dielectric material 112 having a metallization catalyst 114 dispersed therein. The dielectric material 112 may be any appropriate dielectric material, including, but not limited to, epoxy-polymer blend materials, silicon dioxide and silicon nitride, as well as low-k and ultra low-k dielectrics (dielectric constants less than about 3.6), including but not limited to carbon doped dielectrics, fluorine doped dielectrics, porous dielectrics, organic polymeric dielectrics, silicon based polymeric dielectrics, and the like. The metallization catalyst 114 may be any appropriate material which may initiate the subsequent deposition of a metal layer, as will be discussed. The metallization catalyst 114 may include materials including but not limited to palladium salts (such as palladium acetate, palladium bis-triphenyl phosphine, and the like), silver salts, copper salts, platinum salts, nickel salts, and the like.

The microelectronic dielectric layer 110 may be formed by any process known in the art, including, but not limited to, doping, co-deposition, and the like. Furthermore, the microelectronic dielectric layer 110 may include a filler material (not shown) to assist in the prevention of the thermal expansion issues, as will be understood by those skilled in the art. In one embodiment, the filler material (not shown) may have a maximum filler size of about 1 μm and an average filler size of less than about 0.3 μm. In a specific example, the microelectronic dielectric layer 110 may comprise an epoxy-polymer blend for the dielectric material 112 and may further include a silica filler material.

As shown in FIG. 2, a primer layer 120 may be formed on a first surface 116 of the microelectronic dielectric layer 110. In one embodiment of the present description, the primer layer 120 may comprise an organic polymer film that selected to be resistant to subsequent chemical processes, including activation and metallization processes, as will be discussed. In a further embodiment of the present description, the primer layer 120 can be composed of an appropriate organic material, including, but is not limited to an epoxy-phenol or an epoxy-imide material formed with an ester-cyanate or ester-phenol based curing process. In an embodiment of the present description, the primer layer 120 can be formed by any appropriate technique, including but not limited to spin/slit coating, film lamination, or the like.

In an embodiment of the present description, the primer layer 120 may be relatively thin. In one embodiment, the primer layer 120 may have a thickness T of less than about 1 μm. With a relatively thin primer layer 120, the material formulation thereof can be much less demanding in terms of designing for minimizing the effects of thermal expansion, as will be understood to those skilled in the art.

The primer layer 120 may include a filler material (not shown), which may have a relatively small particle size. In one embodiment, the filler material may have a particle size of less than about 100 nm, such that any side reactions therewith are avoided during subsequent processing steps, as will be understood to those skilled in the art. It is noted that using a primer layer 120 without a filler material may be advantageous, as it will entirely avoid such side reactions. It is understood that the primer layer 120 need not be removed, such that it will be a permanent feature of the build-up layer resulting from the embodiments of the present description.

As shown in FIG. 3, a recess 130 may be formed through the primer layer 120 and into the microelectronic dielectric layer 110, wherein the recess 130 may include at least one exposed surface of the microelectronic dielectric layer 110, illustrated as sidewalls 132 and a bottom surface 134. In one embodiment of the present description, the recess 130 may be formed by laser ablation (illustrated as arrow 125), such as with an excimer layer, which ablates away desired portions of the primer layer 120 and the microelectronic dielectric layer 110.

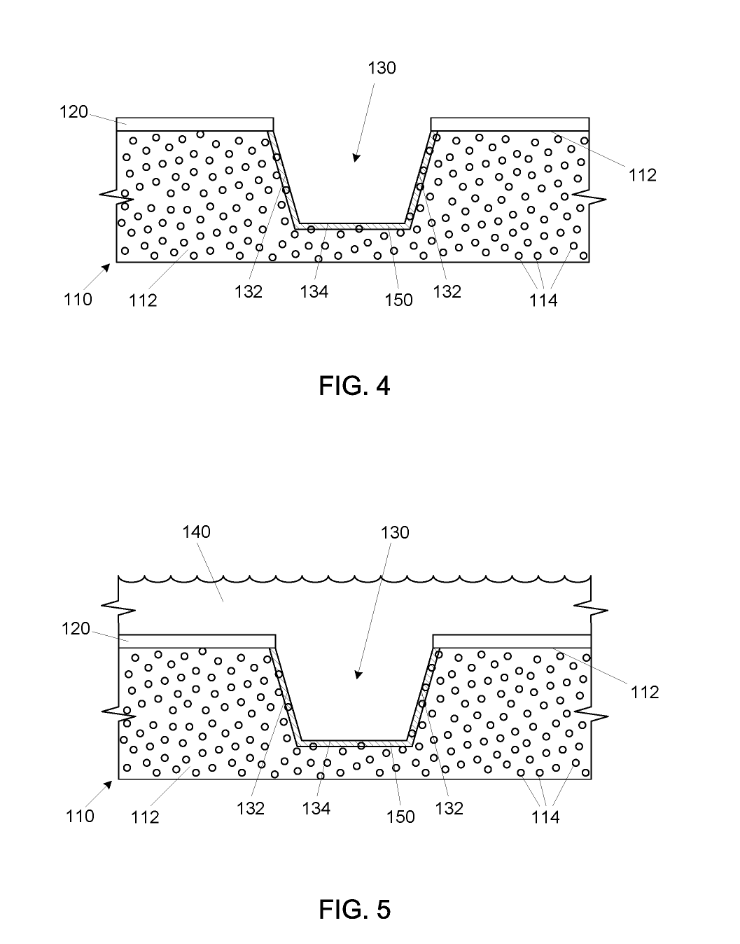

As shown in FIG. 4, when laser ablation 125 (see FIG. 3) is used to form the recess 130, the process may will bring the metallization catalyst 114 of microelectronic dielectric layer 110 at the exposed surfaces of the microelectronic dielectric layer 110 within the recess 130 (e.g. sidewalls 132 and bottom surface 134) into an oxidation state for catalytic activity (e.g. activated), thus forming an activated layer 150. However, if laser ablation 125 (see FIG. 3) is not used to form the recess 130 or if it creates insufficient activation, the exposed surfaces of the microelectronic dielectric layer 110 within the recess 130 (e.g. sidewalls 132 and bottom surface 134) may be activated by immersion in an activation solution 140, as shown in FIG. 5. The activation solution 140 will bring the metallization catalyst 114 of microelectronic dielectric layer 110 at the exposed surfaces of the microelectronic dielectric layer 110 within the recess 130 (e.g. sidewalls 132 and bottom surface 134) into an oxidation state for catalytic activity, thus forming the activated layer 150.

The activation solution 140, if used, may be any appropriate reduction solution, such as dimethyborane. The various components and processes used for catalytic activation are well known to those skilled in the art, and for the sake of brevity and conciseness will not be described or illustrated herein.

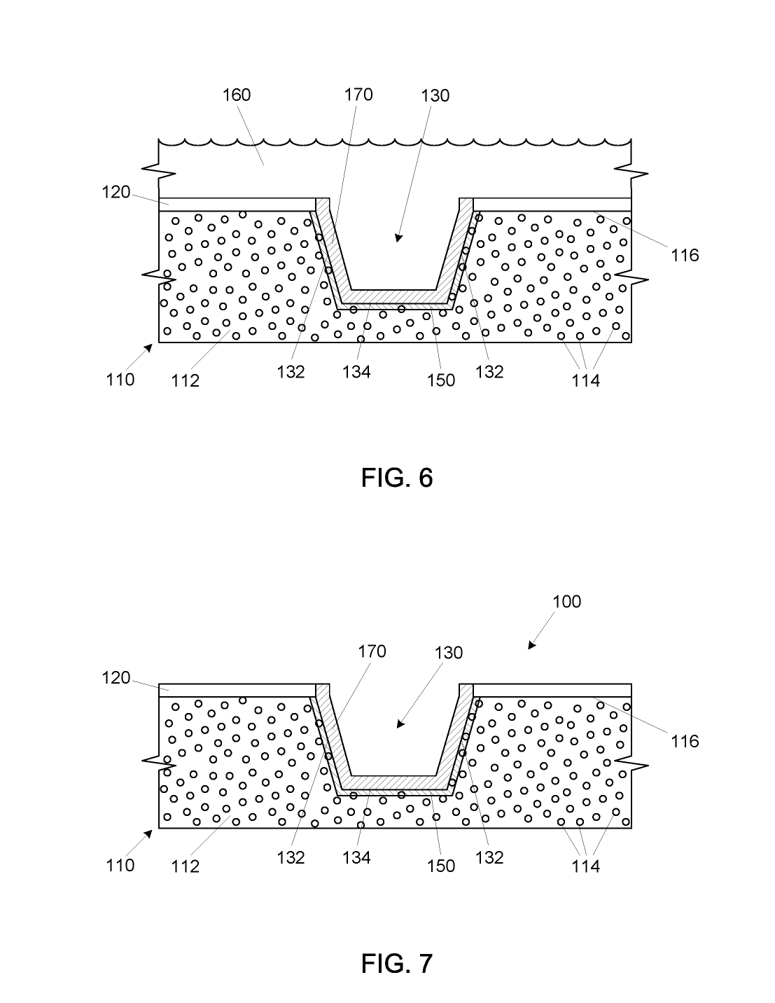

As shown in FIG. 6, the microelectronic dielectric layer 110 may be removed from the activation solution 140 (see FIG. 4), if such an activation step is needed, and immersed in a deposition solution 160 to form a metal layer 170 on the activated layer 150. As illustrated, the deposition may result in a substantially conformal metal layer 170. The deposition solution 160 may be any appropriate solution, such as an electroless solution comprising a metal salt, a reducing agent, and pH mediator (if required) in aqueous media. In one embodiment, the metal salt may comprise a copper salt. The various components and processes used for electroless deposition are well known to those skilled in the art, and for the sake of brevity and conciseness will not be described or illustrated herein.

As shown in FIG. 7, the microelectronic dielectric layer 110 may be removed from the plating solution 160 to form at least a portion of a build-up layer 100. It is understood that the process of the present description may be used to form a plurality microelectronic dielectric layers 110 and metal layers 170 for the build-up layer 100, wherein the metal layers 170 may form at least a portion of the conductive trace and/or conductive vias within the build-up layer 100.

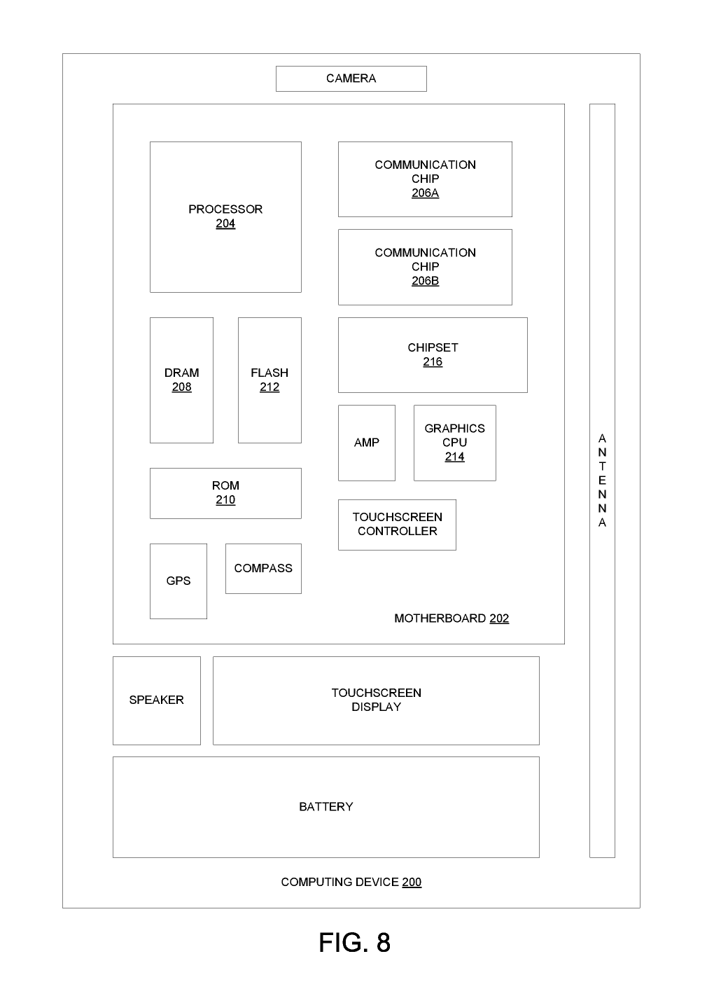

FIG. 8 illustrates a computing device 200 in accordance with one implementation of the present description. The computing device 200 houses a board 202. The board may include a number of microelectronic components, including but not limited to a processor 204, at least one communication chip 206A, 206B, volatile memory 208, (e.g., DRAM), non-volatile memory 210 (e.g., ROM), flash memory 212, a graphics processor or CPU 214, a digital signal processor (not shown), a crypto processor (not shown), a chipset 216, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker (not shown), a camera, and a mass storage device (not shown) (such as hard disk drive, compact disk (CD), digital versatile disk (DVD), and so forth). Any of the microelectronic components may be physically and electrically coupled to the board 202. In some implementations, at least one of the microelectronic components may be a part of the processor 204.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others. The term “processor” may refer to any device or portion of a device that processes electronic data from registers and/or memory to transform that electronic data into other electronic data that may be stored in registers and/or memory.

Any of the microelectronic components within the computing device 200 may include a build-up layer comprising a microelectronic dielectric layer comprising a dielectric material with a metallization catalyst dispersed therein, and a primer layer formed on the microelectronic dielectric layer, as described herein.

In various implementations, the computing device may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

It is understood that the subject matter of the present description is not necessarily limited to specific applications illustrated in FIGS. 1-7. The subject matter may be applied to other microelectronic device and assembly applications, as will be understood to those skilled in the art.

The following examples pertain to further embodiments, wherein Example 1 is a method of fabricating a microelectronic build-up layer, comprising forming a microelectronic dielectric layer comprising a dielectric material with a metallization catalyst dispersed therein, wherein the microelectronic dielectric layer includes a first surface; forming a primer layer on the microelectronic dielectric layer first surface; forming a recess through the primer layer and into the microelectronic dielectric layer; and forming a metal layer adjacent the microelectronic dielectric layer within the recess.

In Example 2, the subject matter of Example 1 can optionally include forming the recess through the primer layer and into the microelectronic dielectric layer comprising laser ablating a recess through the primer layer and into the microelectronic dielectric layer.

In Example 3, the subject matter of either Example 1 or 2 can optionally include forming the microelectronic dielectric layer comprising the dielectric material with the metallization catalyst dispersed therein comprising an epoxy-polymer blend dielectric material.

In Example 4, the subject matter of either Example 1 or 2 can optionally include forming the microelectronic dielectric layer comprising the dielectric material with the metallization catalyst dispersed therein comprising a metallization catalyst selected from the group consisting of palladium salts, silver salts, copper salts, platinum salts, and nickel salts.

In Example 5, the subject matter of either Example 1 or 2 can optionally include forming the primer layer on the microelectronic dielectric layer first surface comprises forming an organic polymer primer layer on the microelectronic dielectric layer first surface.

In Example 6, the subject matter of Example 5 can optionally include forming the organic polymer primer layer on the microelectronic dielectric layer first surface comprising forming an organic polymer primer layer selected from the group consisting of epoxy-phenol materials and epoxy-imide materials.

In Example 7, the subject matter of either Examples 1 or 2 can optionally include forming the metal layer on the dielectric material layer within the recess comprising activating the microelectronic dielectric layer within the recess to form an activated layer within the dielectric material layer; and depositing a metal layer on the activated layer.

In Example 8, the subject matter of Example 7 can optionally include activating the microelectronic dielectric layer comprising immersing the microelectronic dielectric layer and primer layer in an activation solution.

In Example 9, the subject matter of Example 8 can optionally include immersing the microelectronic dielectric layer and primer layer in the activation solution comprising immersing the microelectronic dielectric layer and primer layer in a dimethylborane activation solution.

In Example 10, the subject matter of Example 7 can optionally include depositing a metal layer on the activated layer comprising immersing the activated layer in a deposition solution.

In Example 11, the subject matter of Example 10 can optionally include immersing the activated layer in a deposition solution comprising immersing activated layer in an aqueous deposition solution comprising a metal salt and a reducing agent.

In Example 12, the subject matter of Example 11 can optionally include immersing the activated layer in an aqueous deposition solution comprising a metal salt and a reducing agent comprising immersing the activated layer in an aqueous deposition solution comprising a copper salt and a reducing agent.

The following examples pertain to further embodiments, wherein Example 13 is a microelectronic build-up layer, comprising a microelectronic dielectric layer comprising a dielectric material with a metallization catalyst dispersed therein, wherein the microelectronic dielectric layer includes a first surface; a primer layer on the microelectronic dielectric layer first surface; a recess through the primer layer and into the microelectronic dielectric layer; and a metal layer adjacent the microelectronic dielectric layer within the recess.

In Example 14, the subject matter of Example 13 can optionally include the recess through the primer layer and into the microelectronic dielectric layer comprising a laser ablated recess through the primer layer and into the microelectronic dielectric layer.

In Example 15, the subject matter of Example 13 can optionally include the microelectronic dielectric layer comprising the dielectric material with the metallization catalyst dispersed therein comprising an epoxy-polymer blend dielectric material.

In Example 16, the subject matter of any of Examples 13 to 15 can optionally include the microelectronic dielectric layer comprising the dielectric material with the metallization catalyst dispersed therein comprising a metallization catalyst selected from the group consisting of palladium salts, silver salts, copper salts, platinum salts, and nickel salts.

In Example 17, the subject matter of any of Examples 13 to 15 can optionally include the primer layer on the microelectronic dielectric layer first surface comprising an organic polymer primer layer on the microelectronic dielectric layer first surface.

In Example 18, the subject matter of Example 17 can optionally include the organic polymer primer layer on the microelectronic dielectric layer first surface comprising an organic polymer primer layer selected from the group consisting of epoxy-phenol materials and epoxy-imide materials.

In Example 19, the subject matter of any of Examples 13 to 15 can optionally include an activated layer disposed between the metal layer and the dielectric material layer within the recess.

In Example 20, the subject matter of any of Examples 13 to 15 can optionally include the metal layer comprising a conformal metal layer.

In Example 21, the subject matter of any of Examples 13 to 15 can optionally include the metal layer comprising a copper layer.

The following examples pertain to further embodiments, wherein Example 22 is a electronic system, comprising a board; and a microelectronic component attached to the board, wherein the microelectronic component includes microelectronic build-up layer, comprising a microelectronic dielectric layer comprising a dielectric material with a metallization catalyst dispersed therein, wherein the microelectronic dielectric layer includes a first surface; a primer layer on the microelectronic dielectric layer first surface; a recess through the primer layer and into the microelectronic dielectric layer; and a metal layer adjacent the microelectronic dielectric layer within the recess.

In Example 23, the subject matter of Example 22 can optionally include the recess through the primer layer and into the microelectronic dielectric layer comprising a laser ablated recess through the primer layer and into the microelectronic dielectric layer.

In Example 24, the subject matter of Example 22 can optionally include the microelectronic dielectric layer comprising the dielectric material with the metallization catalyst dispersed therein comprising an epoxy-polymer blend dielectric material.

In Example 25, the subject matter of any of Examples 22 to 24 can optionally include the microelectronic dielectric layer comprising the dielectric material with the metallization catalyst dispersed therein comprising a metallization catalyst selected from the group consisting of palladium salts, silver salts, copper salts, platinum salts, and nickel salts.

In Example 26, the subject matter of any of Examples 22 to 24 can optionally include the primer layer on the microelectronic dielectric layer first surface comprising an organic polymer primer layer on the microelectronic dielectric layer first surface.

In Example 27, the subject matter of Example 26 can optionally include the organic polymer primer layer on the microelectronic dielectric layer first surface comprising an organic polymer primer layer selected from the group consisting of epoxy-phenol materials and epoxy-imide materials.

In Example 28, the subject matter of any of Examples 22 to 24 can optionally include an activated layer disposed between the metal layer and the dielectric material layer within the recess.

In Example 29, the subject matter of any of Examples 22 to 24 can optionally include the metal layer comprising a conformal metal layer.

In Example 30, the subject matter of any of Examples 22 to 24 can optionally include the metal layer comprising a copper layer.

Having thus described in detail embodiments of the present description, it is understood that the present description defined by the appended claims is not to be limited by particular details set forth in the above description, as many apparent variations thereof are possible without departing from the spirit or scope thereof.

1.-25. (canceled)

26. A method of fabricating a microelectronic build-up layer, comprising:
forming a microelectronic dielectric layer comprising a dielectric material with a metallization catalyst dispersed therein, wherein the microelectronic dielectric layer includes a first surface;
forming a primer layer on the microelectronic dielectric layer first surface;
forming a recess through the primer layer and into the microelectronic dielectric layer; and
forming a metal layer adjacent the microelectronic dielectric layer within the recess.

27. The method of claim 26, wherein forming the recess through the primer layer and into the microelectronic dielectric layer comprises laser ablating a recess through the primer layer and into the microelectronic dielectric layer.

28. The method of claim 26, wherein forming the microelectronic dielectric layer comprising the dielectric material with the metallization catalyst dispersed therein comprises an epoxy-polymer blend dielectric material.

29. The method of claim 26, wherein forming the microelectronic dielectric layer comprising the dielectric material with the metallization catalyst dispersed therein comprises a metallization catalyst selected from the group consisting of palladium salts, silver salts, copper salts, platinum salts, and nickel salts.

30. The method of claim 26, wherein forming the primer layer on the microelectronic dielectric layer first surface comprises forming an organic polymer primer layer on the microelectronic dielectric layer first surface.

31. The method of claim 30, wherein forming the organic polymer primer layer on the microelectronic dielectric layer first surface comprises forming an organic polymer primer layer selected from the group consisting of epoxy-phenol materials and epoxy-imide materials.

32. The method of claim 26, wherein forming the metal layer on the dielectric material layer within the recess comprises:
activating the microelectronic dielectric layer within the recess to form an activated layer within the dielectric material layer; and
depositing a metal layer on the activated layer.

33. The method of claim 32, wherein activating the microelectronic dielectric layer comprises immersing the microelectronic dielectric layer and primer layer in an activation solution.

34. The method of claim 33, wherein immersing the microelectronic dielectric layer and primer layer in an activation solution comprising immersing the microelectronic dielectric layer and primer layer in a dimethylborane activation solution.

35. The method of claim 32, wherein depositing a metal layer on the activated layer comprises immersing the activated layer in a deposition solution.

36. The method of claim 35, wherein immersing the activated layer in a deposition solution comprising immersing activated layer in an aqueous deposition solution comprising a metal salt and a reducing agent.

37. The method of claim 36, wherein immersing the activated layer in an aqueous deposition solution comprising a metal salt and a reducing agent comprises immersing the activated layer in an aqueous deposition solution comprising a copper salt and a reducing agent.

38. A microelectronic build-up layer, comprising:
a microelectronic dielectric layer comprising a dielectric material with a metallization catalyst dispersed therein, wherein the microelectronic dielectric layer includes a first surface;
a primer layer on the microelectronic dielectric layer first surface;
a recess through the primer layer and into the microelectronic dielectric layer; and
a metal layer adjacent the microelectronic dielectric layer within the recess.

39. The microelectronic build-up layer of claim 38, wherein the recess through the primer layer and into the microelectronic dielectric layer comprises a laser ablated recess through the primer layer and into the microelectronic dielectric layer.

40. The microelectronic build-up layer of claim 38, wherein the microelectronic dielectric layer comprising the dielectric material with the metallization catalyst dispersed therein comprises an epoxy-polymer blend dielectric material.

41. The microelectronic build-up layer of claim 38, wherein the microelectronic dielectric layer comprising the dielectric material with the metallization catalyst dispersed therein comprises a metallization catalyst selected from the group consisting of palladium salts, silver salts, copper salts, platinum salts, and nickel salts.

42. The microelectronic build-up layer of claim 38, wherein the primer layer on the microelectronic dielectric layer first surface comprises an organic polymer primer layer on the microelectronic dielectric layer first surface.

43. The microelectronic build-up layer of claim 42, wherein the organic polymer primer layer on the microelectronic dielectric layer first surface comprises an organic polymer primer layer selected from the group consisting of epoxy-phenol materials and epoxy-imide materials.

44. The microelectronic build-up layer of claim 38, further comprising an activated layer disposed between the metal layer and the dielectric material layer within the recess.

45. The microelectronic build-up layer of claim 38, wherein the metal layer comprises a conformal metal layer.

46. The microelectronic build-up layer of claim 38, wherein the metal layer comprises a copper layer.

47. A electronic system, comprising:
a board; and
a microelectronic component attached to the board, wherein the microelectronic component includes microelectronic build-up layer, comprising:
a microelectronic dielectric layer comprising a dielectric material with a metallization catalyst dispersed therein, wherein the microelectronic dielectric layer includes a first surface;
a primer layer on the microelectronic dielectric layer first surface;
a recess through the primer layer and into the microelectronic dielectric layer; and
a metal layer adjacent the microelectronic dielectric layer within the recess.

48. The electronic system of claim 47, wherein the recess through the primer layer and into the microelectronic dielectric layer comprises a laser ablated recess through the primer layer and into the microelectronic dielectric layer.

49. The electronic system of claim 47, wherein the primer layer on the microelectronic dielectric layer first surface comprises an organic polymer primer layer on the microelectronic dielectric layer first surface.

50. The electronic system of claim 47, further comprising an activated layer disposed between the metal layer and the dielectric material layer within the recess.
